(19) United States
(12) Patent Application Publication
(10) Pub. No.: US 2016/0172294 A1
(43) Pub. Date: Jun. 16, 2016

(54) HIGH ASPECT RATIO STRUCTURE

(71) Applicant: MACRONIX International Co., Ltd., Hsinchu (TW)

(72) Inventors: Sheng-Yuan Chang, Hsinchu (TW); An-Chyi Wei, Hsinchu (TW); Nan-Tsu Lian, Hsinchu (TW); Ta-Hone Yang, Hsinchu (TW); Kuang-Chao Chen, Hsinchu (TW)

(21) Appl. No.: 14/571,686

(22) Filed: Dec. 16, 2014

(51) Int. Cl. H01L 23/528; H01L 23/532; H01L 23/522

(52) U.S. Cl. CPC H01L 23/528; H01L 23/5226; H01L 23/53295; H01L 23/5222

(57) ABSTRACT

A high aspect ratio structure is provided. The high aspect ratio structure includes a substrate, a plurality of stack structures, and a plurality of support structures. The stack structures are disposed on the substrate, and a trench is formed between adjacent two stack structures. Each of the stack structures includes a plurality of first material layers and a plurality of second material layers. The second material layers and the first material layers are disposed alternately. The support structures are respectively disposed between the substrate and the stack structures, wherein each of the support structures has a concave-convex surface.

### BACKGROUND OF THE INVENTION

1. Field of the Invention

The invention relates to a high aspect ratio structure.

2. Description of Related Art

As the sizes of semiconductor devices decrease, in order to achieve high density and high performance, fabrication of semiconductor devices has evolved into stacking upward in the vertical direction, such that the wafer area can be used more efficiently.

In a vertical memory device, as the elements are stacked upward, the relative relationship between the elements and the configuration of the stack structure also become complicated. For example, when forming a high aspect ratio (HAR) structure, e.g. a higher aspect ratio trench, the challenge is that the structures on two sides of the trench may bend or collapse easily. This phenomenon causes difficulty in the follow-up fabrication processes and has adverse effects on the electrical test of the semiconductor device. Hence, how to prevent the high aspect ratio structure from bending or collapse is an important issue that needs to be overcome in this field.

### SUMMARY OF THE INVENTION

The invention provides a high aspect ratio structure for improving strength and an anti-collapse property of a stack structure.

The invention provides a high aspect ratio structure that includes a substrate, a plurality of stack structures, and a plurality of support structures. The stack structures are disposed on the substrate. A trench is formed between adjacent two stack structures. Each of the stack structures includes a plurality of first material layers and a plurality of second material layers. The first and second material layers are disposed alternately. The support structures are respectively disposed between the substrate and the stack structures, wherein each of the support structures has a concave-convex surface.

In an embodiment of the invention, the concave-convex surface has a rectangular shape, a triangular shape, a rhombic shape, or a combination of the foregoing.

In an embodiment of the invention, the substrate includes a plurality of first grooves, and the support structures are respectively embedded in the first grooves of the substrate.

In an embodiment of the invention, the support structures fill the first grooves of the substrate and cover a portion of a surface of the substrate.

In an embodiment of the invention, the support structures are disposed in the first grooves of the substrate and formed conformally with the first grooves, and each of the support structures comprises a second groove.

In an embodiment of the invention, the high aspect ratio structure further includes a plurality of first dielectric layers respectively embedded in the second groove of each of the support structures and covering a surface of the support structure.

In an embodiment of the invention, a shape of the first dielectric layer includes a T shape.

In an embodiment of the invention, a shape of the first groove includes a rectangular shape, a triangular shape, a rhombic shape, or a combination of the foregoing.

In an embodiment of the invention, the high aspect ratio structure further includes a first support layer disposed between the substrate and the support structures.

In an embodiment of the invention, the high aspect ratio structure further includes a plurality of first dielectric layers respectively embedded in a second groove of each of the support structures and covering a surface of the support structure.

In an embodiment of the invention, a shape of the first dielectric layer includes a T shape.

In an embodiment of the invention, a shape of the support structure comprises a T shape, a U shape, a nail shape, or a combination of the foregoing.

In an embodiment of the invention, a Young's modulus of the support structure is greater than a Young's modulus of the first material layers or a Young's modulus of the second material layers.

In an embodiment of the invention, a material of the support structures comprises silicon nitride, silicon carbide, metalloid, or a combination of the foregoing.

In an embodiment of the invention, the high aspect ratio structure further includes a plurality of second support layers respectively disposed on the stack structures.

In an embodiment of the invention, an aspect ratio of the trench is in a range of 10-180.

In an embodiment of the invention, the high aspect ratio structure further includes a plurality of conductive pillars disposed in the trenches; and a charge storage layer disposed between the stack structures and the conductive pillars.

In an embodiment of the invention, at least a portion of each of the support structures is embedded in the substrate.

In an embodiment of the invention, at least a portion of the support structures protrudes on a surface of the substrate.

In an embodiment of the invention, the first material layers and the second material layers include conductive material, dielectric material or the combination thereof.

Based on the above, in the high aspect ratio structure provided by the invention, the support structure is formed between the substrate and the stack structure to improve the strength at the bottom of the high aspect ratio structure and prevent bending or collapse of the stack structure. In particular, for a structure having the trench of higher aspect ratio between the stack structures, by disposing the support structure having greater Young's modulus than the material layer under the stack structure, the overall Young's modulus of the high aspect ratio structure is improved. Moreover, each support structure has the concave-convex surface, such that the support structure can be fitted with the stack structure thereover or the substrate thereunder, thereby improving the strength and anti-collapse property of the high aspect ratio structure and preventing bending or collapse.

To make the aforementioned and other features and advantages of the invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain the principles of the invention.

FIG. 1A is a schematic cross-sectional view illustrating a high aspect ratio structure according to an embodiment of the invention.

FIG. 1B is a schematic cross-sectional view illustrating a high aspect ratio structure according to another embodiment of the invention.

FIG. 2 is a schematic cross-sectional view illustrating a high aspect ratio structure according to yet another embodiment of the invention.

FIG. 3 is a schematic cross-sectional view illustrating a high aspect ratio structure according to yet another embodiment of the invention.

FIG. 4A to FIG. 4G are schematic cross-sectional views illustrating a fabricating method of a high aspect ratio structure according to an embodiment of the invention.

FIG. 5A to FIG. 5C are schematic cross-sectional views illustrating a fabricating method of a high aspect ratio structure according to another embodiment of the invention.

FIG. 6A to FIG. 6E are schematic cross-sectional views illustrating a fabricating method of a high aspect ratio structure according to yet another embodiment of the invention.

### DESCRIPTION OF THE EMBODIMENTS

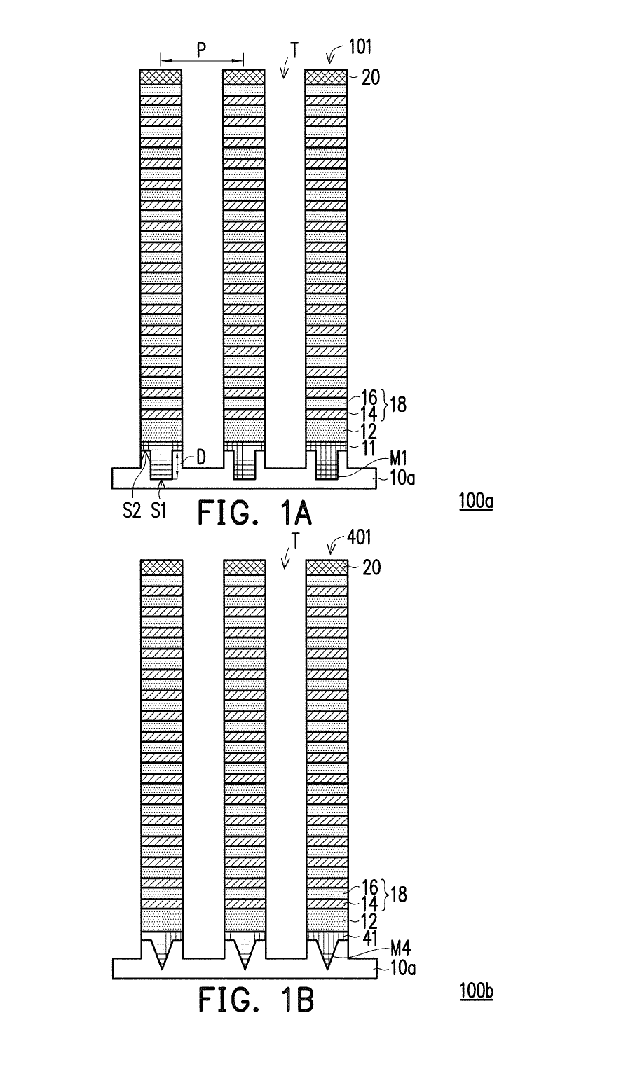

FIG. 1A is a schematic cross-sectional view illustrating a high aspect ratio structure according to an embodiment of the invention.

With reference to FIG. 1A, a high aspect ratio structure 100a includes a substrate 10a, a plurality of stack structures 101, and a plurality of support structures 11. The substrate 10a may include a semiconductor material, an insulator material, a conductive material, or any combination of the foregoing materials. A material of the substrate 10a is a material composed of at least one selected from a group consisting of Si, SiO₂, Ge, SiGe, GaP, GaAs, SiC, SiGeC, InAs, and InP, or any physical structure suitable for a fabricating process of the invention, for example. The substrate 10a includes a single-layer structure or a multi-layer structure. In addition, a silicon on insulator (SOI) substrate may be used. The substrate 10a is silicon or silicon germanium, for example. In an embodiment, the substrate 10a is a patterned substrate that includes a plurality of grooves M1, for example. The groove M1 has a rectangular shape, a triangular shape, a rhombic shape, or a combination of the foregoing, for example. However, the invention is not limited thereto. The rectangular shape is a U shape; and the triangular shape is a V shape, for example. In this embodiment, the groove M1 has the U shape, for example.

The stack structures 101 are disposed on the substrate 10a. A trench T is formed between adjacent two stack structures 101. The trench T may be formed with any length, width, or shape. The trench T may be a wide trench or a narrow trench. In an embodiment, a width of the trench T is in a range of 5 nm to 30 nm, for example. A depth of the trench T is in a range of 500 nm to 5,000 nm, for example. In other words, the trench T has a higher aspect ratio. In an embodiment, the aspect ratio of the trench T is in a range of 10-180, for example. A cross section of the trench T may be in any shape, such as a V shape, a U shape, a rhombic shape, or a combination of the foregoing, for example. However, it should be noted that the invention is not limited thereto. In this embodiment, the cross section of the trench T has the U shape, for example. Moreover, in an embodiment, a pitch P between adjacent two stack structures 101 is in a range of 10 nm to 86 nm, for example.

Again, with reference to FIG. 1A, each of the stack structures 101 includes a dielectric material layer 12, a plurality of material layers 14, and a plurality of material layers 16. The dielectric material layer 12 includes oxide, nitride, oxynitride, or a low dielectric constant material having a dielectric constant smaller than 4. In an embodiment, the dielectric material layer 12 is a bottom oxide layer (BOX), for example. A thickness of the dielectric material layer 12 is in a range of 10 nm to 900 nm, for example. In an embodiment, a shape of the dielectric material layer 12 includes a “ [symbol] ” shape, a T shape, or a combination of the foregoing.

The material layers 14 and the material layers 16 are disposed on the dielectric material layer 12. The material layers 14 and the material layers 16 are disposed alternately. In an embodiment, the material layer 14 is disposed on the dielectric material layer 12, and the material layer 16 is disposed on the material layer 14. The material layers 14 and the material layers 16 are alternately stacked upward on the substrate 10a, so as to finial a plurality of the stack structures 101. The material layer 14 and the material layer 16 include a conductive material, a dielectric material, an insulating material, or a combination thereof. The material layer 14 and the dielectric layer 16 may be the same or different. The material layer 16 and the dielectric material layer 12 may be formed of the same or different materials. The material of the material layer 16 includes oxide, nitride, oxynitride, or a low dielectric constant material having a dielectric constant smaller than 4. A thickness of the material layer 16 is in a range of 200 angstrom to 1000 angstrom, for example. In an embodiment, the thickness of the material layer 16 is 450 angstrom, for example. A material of the material layer 14 includes an undoped semiconductor or a doped semiconductor, such as polysilicon or doped polysilicon. A thickness of the material layer 14 is in a range of 100 angstrom to 1000 angstrom, for example. In an embodiment, the thickness of the material layer 14 is 200 angstrom, for example. In an embodiment, the stack structure 101 is formed by alternately disposing a polysilicon layer and an oxide layer. In another embodiment, the stack structure 101 is formed by alternately disposing a nitride layer and an oxide layer. However, the invention is not limited thereto.

In another embodiment, each of the stack structures 101 is formed by stacking a plurality of composite layers 18 upward on the substrate 10a. Each of the composite layers 18 may be composed of one material layer 14 and one material layer 16. Each of the composite layers 18 may also be composed of one material layer 14 and multiple material layers 16. Each of the composite layers 18 may also be composed of multiple material layers 14 and one material layer 16. In an embodiment, each of the composite layers 18 is a multi-layer structure including two or more layers of the polysilicon layer and the oxide layer, for example. In FIG. 1A, the stack structure 101 includes sixteen composite layers 18, for example. However, the invention is not limited thereto.

Again, with reference to FIG. 1A, the high aspect ratio structure 100a selectively includes a support layer 20. The support layer 20 is disposed on the stack structure 101. The support layer 20 may include a single layer or multiple layers. The support layer 20 includes a nitride layer, and a material thereof is silicon nitride or other suitable materials, for example. A thickness of the support layer 20 is in a range of 10 nm to 200 nm, for example. It is worth mentioning that the support layer 20 may be formed of a material, such as silicon nitride, which has a Young's modulus greater than a Young's modulus of the material layer 14 or the material layer 16. Therefore, when the support layer 20 having greater Young's modulus than the material layer 14 (e.g. polysilicon) is disposed on top of the stack structure 101, an overall Young's modulus of the stack structure 101 is improved to increase the anti-collapse property of the structure.

A plurality of the support structures 11 are respectively disposed between the substrate 10a and the stack structures 101. The support structures 11 are disposed between the substrate 10a and the dielectric material layer 12, for example. In an embodiment, the support structures 11 are respectively embedded in the grooves M1 of the substrate 10a and cover the grooves M1. In another embodiment, the support structures 11 fill the grooves M1 of the substrate 10a and cover a portion of a surface of the substrate 10a. The support structure 11 has a T shape, a U shape, a nail shape, or a combination of the foregoing. In this embodiment, the support structure 11 has the T shape, for example. For example, according to FIG. 1A, the T shape includes an upper part covering a portion of the substrate 10a and a lower part embedded in the substrate 10a. However, it should be noted that the invention is not limited thereto.

Each of the support structures 11 has a concave-convex surface. As shown in FIG. 1A, a distance D from a convex top surface S1 to a convex bottom surface S2 of the concave-convex surface is in a range of 10 nm to 300 nm, for example. However, it should be noted that the invention is not limited thereto. The support structure 11 may be any structure that has the concave-convex surface. The concave-convex surface includes a polygon. The concave-convex surface is a rectangular shape, a triangular shape, a rhombic shape, or a combination of the foregoing, for example. The rectangular shape is a U shape, for example. A material of the support structure 11 may be any material that has a Young's modulus greater than the Young's modulus of the material layer 14 or the material layer 16. The material of the support structure 11 may also be any material that has a band gap greater than a band gap of the material layer 14 or the material layer 16. The material of the support structure 11 is an ion-implanted or doped material, for example. The material of the support structure 11 may also be silicon nitride, silicon carbide, metalloid (e.g. aluminum), or a combination of the foregoing. In an embodiment of the invention, the material of the support structure 11 is different from the material of the dielectric material layer 12. A thickness of the support structure 11 is in a range of 10 nm to 300 nm, for example.

It should be noted that, because the support structure 11 has the concave-convex surface, the support structure 11 can be embedded in the groove M1 of the substrate 10a. Accordingly, when the support structure 11 is disposed on the substrate 10a having the groove M1, the support structure 11 can be properly bonded to the substrate 10a to improve the strength and anti-collapse property of the high aspect ratio structure.

In addition, it is known that deformation of the material structure is related to the Young's modulus. As the Young's modulus of the material increases, it becomes more difficult for the structure to deform. Accordingly, when the support structure 11 having greater Young's modulus than the material layer 14 or the material layer 16 is disposed between the substrate 10a and the stack structure 101, the overall Young's modulus of the high aspect ratio structure 100a is improved, such that the stack structure 101 does not deform easily. Moreover, the support structure 11 and the substrate 10a can be fitted to each other, so as to further improve the strength and anti-collapse property of the high aspect ratio structure 100a, thereby preventing bending or collapse.

FIG. 1B is a schematic cross-sectional view illustrating a high aspect ratio structure according to another embodiment of the invention. A difference between a high aspect ratio structure 100b of FIG. 1B and the high aspect ratio structure 100a of FIG. 1A lies in that a groove M4 of the substrate 10a and a support structure 41 are different from the groove M1 and the support structure 11. The same reference numerals are used to represent the same elements, and details thereof are not repeated hereinafter.

With reference to FIG. 1B, the high aspect ratio structure 100b includes the substrate 10a, a plurality of stack structures 401, and a plurality of support structures 41. The substrate 10a is a patterned substrate that includes a plurality of grooves M4, for example. The groove M4 has a rectangular shape, a triangular shape, a rhombic shape, or a combination of the foregoing. In this embodiment, the groove M4 has a V shape, for example.

The support structures 41 are respectively disposed between the substrate 10a and the stack structures 401. The support structures 41 are disposed between the substrate 10a and the dielectric material layer 12, for example. In an embodiment, the support structures 41 are embedded in the grooves M4 of the substrate 10a and cover the grooves M4. In another embodiment, the support structures 41 fill the grooves M4 of the substrate 10a and cover a portion of the surface of the substrate 10a. In this embodiment, the support structure 41 has a nail shape, for example. For example, according to FIG. 1B, the nail shape includes an upper part covering a portion of the substrate 10a and a lower part embedded in the substrate 10a. However, it should be noted that the invention is not limited thereto. Each of the support structures 41 has a concave-convex surface. The support structure 41 may have any shape that includes the concave-convex surface. The concave-convex surface includes a rectangular shape, a triangular shape, a rhombic shape, or a combination of the foregoing. The material and thickness of the support structure 41 may be the same as the material and thickness of the support structure 11, and thus details thereof are not repeated hereinafter.

In the above embodiments, composition material layers in the stack structure or the composite layer are arranged in an order. However, the stack structure and the composite layer of the invention are not limited thereto. The composition material layers may also be arranged randomly. In other words, any structure having a trench of higher aspect ratio that disposes a support structure between the substrate and the stack structures falls within the scope of the invention.

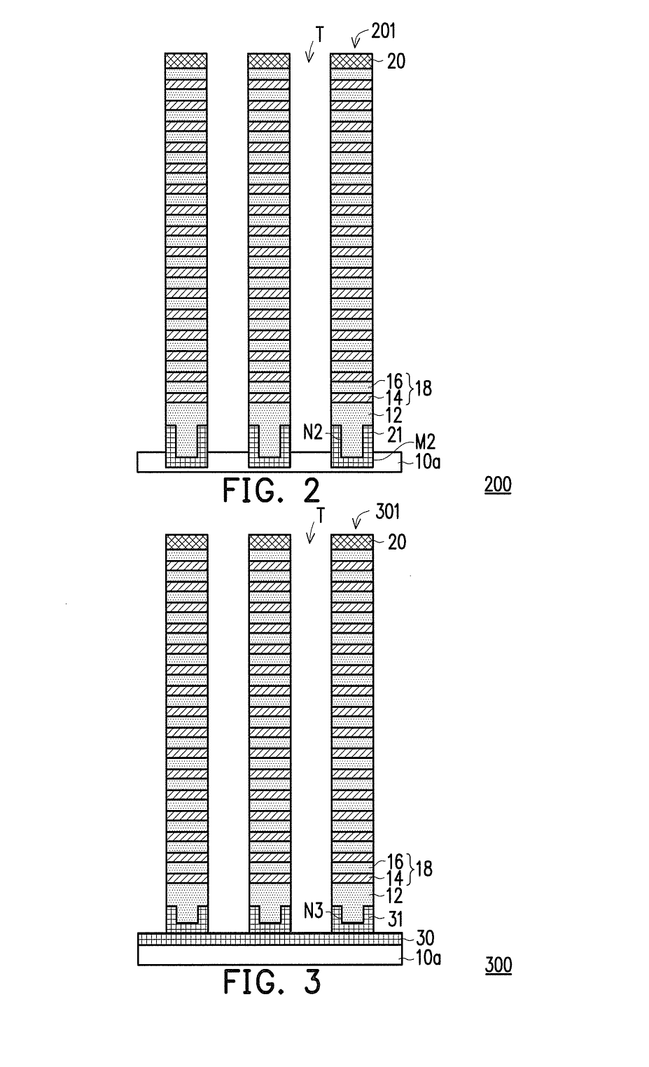

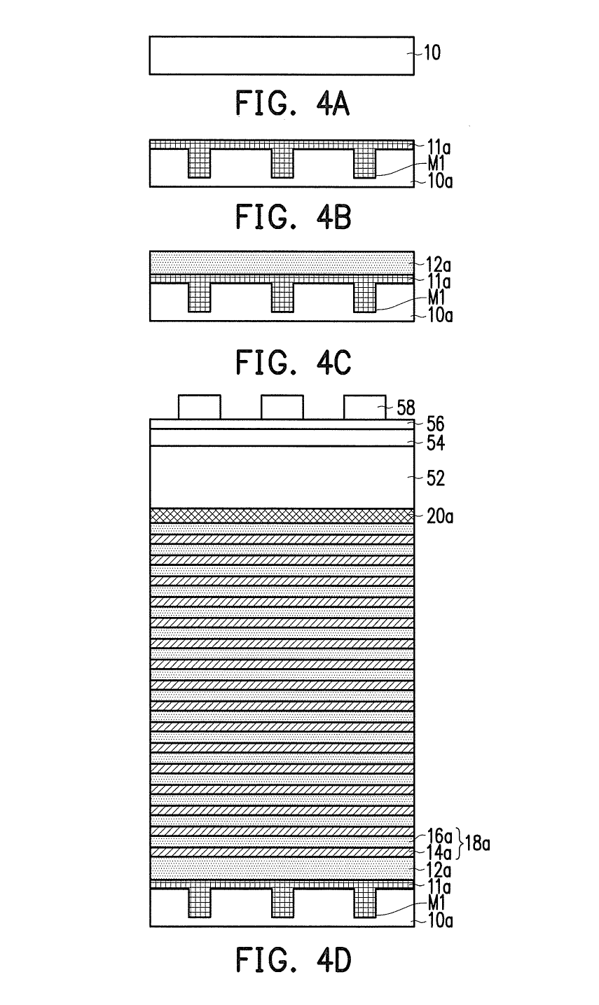

Furthermore, in the high aspect ratio structures 100a and 100b, the support structure 11 has a nail shape or a T shape, for example. However, the invention is not limited thereto. In other embodiments, the support structure 11 may have a U shape or other shapes, as shown in FIG. 2 to FIG. 3.

FIG. 2 is a schematic cross-sectional view illustrating a high aspect ratio structure according to yet another embodiment of the invention. It should be noted that a difference between a high aspect ratio structure 200 of FIG. 2 and the high aspect ratio structure 100a of FIG. 1A lies in that the substrate 10a, a support structure 21, and the dielectric material layer 12 have structures different from the above descriptions.

With reference to FIG. 2, the high aspect ratio structure 200 includes the substrate 10a, a plurality of stack structures 201, and a plurality of support structures 21. The material of the substrate 10a has been specified above and thus is not repeated hereinafter. In this embodiment, the substrate 10a is a patterned substrate, which includes a plurality of grooves M2, for example. The groove M2 has a rectangular shape, a triangular shape, a rhombic shape, or a combination of the foregoing. In this embodiment, the groove M2 has the rectangular shape, for example. In addition, in an embodiment, an outer width of the groove M2 is equal to the width of the stack structure 201 above, for example. However, it should be noted that the invention is not limited thereto.

The support structures 21 are respectively disposed between the substrate 10a and the stack structures 201. The support structures 21 are disposed between the substrate 10a and the dielectric material layer 12, for example. The support structures 21 are disposed in the grooves M2 of the substrate 10a, and are formed conformally with the grooves M2 and protrude on the surface of the substrate 10a, for example. For example, the support structure 21 has a U shape, for example. A bottom of the U shape is embedded in the groove M2 of the substrate 10a, and a portion of two side parts is respectively embedded in the substrate 10a while another portion thereof protrudes on the surface of the substrate 10a, as shown in FIG. 2.

Each of the support structures 21 has a concave-convex surface. The support structure 21 may be any structure that has the concave-convex surface. The concave-convex surface includes a rectangular shape, a triangular shape, a rhombic shape, or a combination of the foregoing. In this embodiment, each of the support structures 21 includes a groove N2. A width of the groove N2 of the support structure 21 is smaller than the width of the groove M2 of the substrate 10a, for example. The material and thickness of the support structure 21 may be the same as the material and thickness of the support structure 11, and thus details thereof are not repeated hereinafter.

Moreover, in this embodiment, the dielectric material layer 12 is respectively embedded in the groove N2 of each of the support structures 21 and covers the surface of the support structure 21, for example. The dielectric material layer 12 has a T shape, for example. For example, according to FIG. 2, the T shape includes an upper part covering the support structure 21 and a lower part embedded in the groove N2 of the support structure 21. However, it should be noted that the invention is not limited thereto.

It should be noted that, because the support structure 21 has the concave-convex surface, the support structure 21 can be embedded in the groove M2 of the substrate 10a. Accordingly, when the support structure 21 is disposed on the substrate 10a having the groove M2, the support structure 21 can be properly bonded to the substrate 10a. In addition, because the support structure 21 has the groove N2, the dielectric material layer 12 formed in the subsequent process can be embedded in the groove N2 of the support structure 21 to be properly bonded to the support structure 21. In other words, in this embodiment, the support structure 21 is simultaneously fitted to the stack structure 201 thereon and the substrate 10a thereunder, so as to significantly improve the strength and anti-collapse property of the high aspect ratio structure.

FIG. 3 is a schematic cross-sectional view illustrating a high aspect ratio structure according to yet another embodiment of the invention. It should be noted that a difference between a high aspect ratio structure 300 of FIG. 3 and the high aspect ratio structure 200 of FIG. 2 lies in that a substrate 10 and a support structure 31 have structures different from the above descriptions. In addition, the high aspect ratio structure 300 further includes a support layer 30.

With reference to FIG. 3, the high aspect ratio structure 300 includes the substrate 10, a plurality of stack structures 301, a plurality of support structures 31, and the support layer 30. In this embodiment, the substrate 10 is a non-patterned substrate, or the substrate 10 has a flat surface, for example.

The support layer 30 is disposed on the substrate 10. The support layer 30 is disposed between the substrate 10 and the support structures 31, for example. The support layer 30 may include a single layer or multiple layers. A material of the support layer 30 may be any material that has a Young's modulus greater than the Young's modulus of the material layer 14 or the material layer 16. The material of the support layer 30 may also be any material that has a band gap greater than the band gap of the material layer 14 or the material layer 16. The material of the support layer 30 may be an ion-implanted or doped material, for example. The material of the support layer 30 may also be silicon nitride, silicon carbide, metalloid (e.g. aluminum), or a combination of the foregoing. In an embodiment, the material of the support layer 30 is the same as or different from the material of the support structure 31 thereon, for example. However, it should be noted that the invention is not limited thereto. A thickness of the support layer 30 is in a range of 10 nm to 300 nm, for example.

The support structures 31 are respectively disposed between the substrate 10 and the stack structures 301. The support structures 31 are disposed between the support layer 30 and the dielectric material layer 12, for example. Each of the support structures 31 has a concave-convex surface. The support structure 31 may be any structure that has the concave-convex surface. The concave-convex surface includes a rectangular shape, a triangular shape, a rhombic shape, or a combination of the foregoing. The support structure 31 has a U shape, for example. In this embodiment, each of the support structures 31 includes a groove N3. A width of the groove N3 of the support structure 31 is smaller than a width of the stack structure 301, for example.

Further, in this embodiment, the dielectric material layer 12 is respectively embedded in the groove N3 of each of the support structures 31 and covers a surface of the support structure 31, for example. The dielectric material layer 12 has a T shape, for example. For example, according to FIG. 3, the T shape includes an upper part covering the support structure 31 and a lower part embedded in the groove N3 of the support structure 31. However, it should be noted that the invention is not limited thereto.

In this embodiment, because the support structure 31 has the groove N3, the dielectric material layer 12 formed in the subsequent process can be embedded in the groove N3 of the support structure 31, so as to be properly bonded to the support structure 31. That is to say, the support structure 31 and the stack structure 301 thereon can be fitted to each other. Moreover, the support layer 30 is disposed between the substrate 10 and the support structure 31, so as to further enhance the stability at the bottom of the high aspect ratio structure 300 to improve the strength and anti-collapse property of the high aspect ratio structure, thereby preventing bending or collapse.

In the above embodiments, each of the support structures has the concave-convex surface, so as to be fitted to the stack structure thereon and the substrate thereunder. However, the shape of the support structure of the invention is not limited to the above. That is, any structure having a trench of higher aspect ratio that disposes a support structure between the substrate and the stack structures or under the stacked structures falls within the scope of the invention.

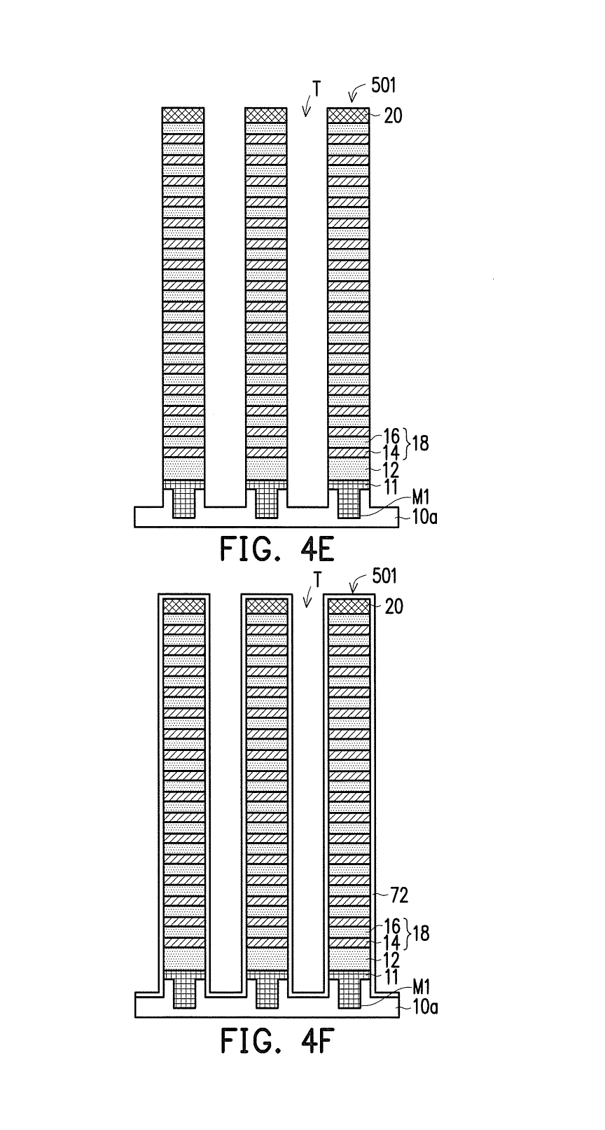

FIG. 4A to FIG. 4G are schematic cross-sectional views illustrating a fabricating method of a high aspect ratio structure according to an embodiment of the invention.

With reference to FIG. 4A and FIG. 4B, a substrate 10 is provided. Next, the substrate 10 is patterned to form a patterned substrate 10a. The substrate 10a includes a plurality of grooves M1. The groove M1 has a rectangular shape, a triangular shape, a rhombic shape, or a combination of the foregoing. In FIG. 4A, the groove M1 has the rectangular shape, for example. However, it should be noted that the invention is not limited thereto. In another embodiment, a groove of the substrate 10a may have a V shape, such as the groove M4 shown in FIG. 1B. Then, a support material layer 11a is formed on the substrate 10a. The support material layer 11a covers the substrate 10a and fills the grooves M1 of the substrate 10a, for example. A material of the support material layer 11a may be any material that has a Young's modulus greater than the Young's modulus of the material layer 14 or the material layer 16. The material of the support material layer 11a may be an ion-implanted or doped material, for example. The material of the support material layer 11a may also be silicon nitride, silicon carbide, metalloid (e.g. aluminum), or a combination of the foregoing. In an embodiment, the material of the support material layer 11a is silicon nitride, for example. A thickness of the support material layer 11a is in a range of 10 nm to 300 nm, for example. A method of forming the support material layer 11a includes performing chemical vapor deposition or metal organic chemical vapor deposition (MOCVD).

With reference to FIG. 4C, a dielectric material layer 12a is formed on the support material layer 11a. A material of the dielectric material layer 12a includes oxide, nitride, oxynitride, or a low dielectric constant material having a dielectric constant smaller than 4. The material of the dielectric material layer 12a is different from the material of the support material layer 11a. In an embodiment, the support material layer 11a is silicon carbide, and the material of the dielectric material layer 12a is silicon oxide, for example. A thickness of the dielectric material layer 12a is in a range of 10 nm to 900 nm, for example. A method of forming the dielectric material layer 12a includes performing thermal oxidation or chemical vapor deposition, for example.

With reference to FIG. 4D, a plurality of composite layers 18a are formed on the dielectric material layer 12a. A method of forming the composite layers 18a includes forming a material layer 14a on the dielectric material layer 12a, and then forming a material layer 16a on the material layer 14a. However, it should be noted that the invention is not limited thereto. In another embodiment, the method of forming the composite layers 18a includes forming a plurality of material layers 14a and a plurality of material layers 16a in sequence on the dielectric material layer 12a. In this embodiment, sixteen composite layers 18a are formed on the dielectric material layer 12a, for example. That is, thirty two material layers 14a and material layers 16a are disposed alternately on the dielectric material layer 12a.

A material of the material layer 14a includes a conductive material, a dielectric material, an insulating material, or a combination thereof. The material layer 14a is polysilicon or doped polysilicon, for example. Alternatively, the material layer 14a may also be a nitride layer. A thickness of the material layer 14a is in a range of 100 angstrom to 1000 angstrom, for example. In an embodiment, the thickness of the material layer 14a is 200 angstrom, for example. A method of forming the material layer 14a includes performing chemical vapor deposition. The material layer 16a includes a conductive material, a dielectric material, an insulating material, or a combination thereof. The material layer 16a may include an oxide layer or a low dielectric constant material having a dielectric constant smaller than 4. A thickness of the material layer 16a is in a range of 200 angstrom to 1000 angstrom, for example. In an embodiment, the thickness of the material layer 16a is 450 angstrom, for example. A method of forming the material layer 16a includes performing thermal oxidation or chemical vapor deposition, for example.

Thereafter, a support material layer 20a is formed on the top composite layer 18a. The support material layer 20a includes a nitride layer, and a material thereof is silicon nitride or other suitable materials, for example. The material of the support material layer 20a may be the same as or different from the material of the support material layer 11a. In an embodiment, the material of the support material layer 20a is different from the materials of the dielectric material layer 12a and the material layer 16a. A thickness of the support material layer 20a is in a range of 10 nm to 200 nm, for example. A method of forming the support material layer 20a includes performing chemical vapor deposition or metal organic chemical vapor deposition (MOCVD).

Then, an advanced patterning film (APF) 52, a dielectric anti-reflective coating film (DARC) 54, a bottom anti-reflective coating film (BARC) 56, and a patterned photoresist layer 58 are formed in sequence on the support material layer 20a.

With reference to FIG. 4D and FIG. 4E, a pattern of the patterned photoresist layer 58 is transferred to the support material layer 20a by performing an etching process on the bottom anti-reflective coating film 56, the dielectric anti-reflective coating film 54, the advanced patterning film 52, and the support material layer 20a with the patterned photoresist layer 58 as a mask. The etching process includes anisotropic etching, such as dry etching, for example. The dry etching may be sputter etching, reactive ion etching, etc. Next, the etched advanced patterning film 52, dielectric anti-reflective coating film 54, bottom anti-reflective coating film 56, and patterned photoresist layer 58 are removed. Then, an etching process is performed on the material layers 16a, the material layers 14a, the dielectric material layer 12a, the support material layer 11a, and the substrate 10a with the patterned support material layer 20a as a mask, so as to form a plurality of stack structures 501, a plurality of trenches T, and a plurality of support structures 11.

The fabricating method of the high aspect ratio structure 100a shown in FIG. 1A is described as above, for example, but not limited to the aforementioned steps. For example, other elements may be further formed by the following steps shown in FIG. 4F to FIG. 4G according to the requirements after the structure of FIG. 4E is formed. Nevertheless, it should be noted that the invention is not limited thereto.

With reference to FIG. 4F, in an embodiment, a charge storage layer 72 is formed on the substrate 10a, a plurality of stack structures 501, and sidewalls of the support structures 11. The charge storage layer 72 may be a single layer or a composite layer including multiple layers. A material of the charge storage layer 72 includes silicon nitride and silicon oxide. In an embodiment, the charge storage layer 72 is a composite layer of an oxide layer/a nitride layer, for example. In another embodiment, the charge storage layer 72 is a composite layer of an oxide layer/a nitride layer/an oxide layer, for example. A method of forming the charge storage layer 72 includes performing chemical vapor deposition or thermal oxidation.

With reference to FIG. 4G, a conductive column 74 is respectively formed in the trenches T. A material of the conductive column 74 includes polysilicon, N+ doped polysilicon, P+ doped polysilicon, a metal material, or a combination of the foregoing, for example. A method of forming the conductive column 74 includes forming a conductive material layer on the substrate 10a and then polishing the conductive material layer to be substantially even with the charge storage layer 72 on the stack structure 501 by chemical mechanical polishing, so as to form a plurality of the conductive pillars 74.

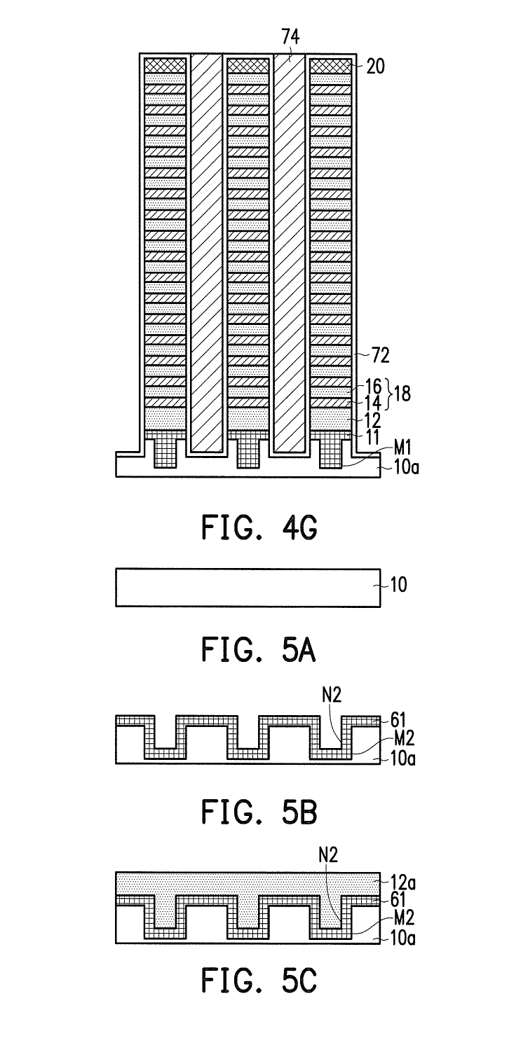

FIG. 5A to FIG. 5C are schematic cross-sectional views illustrating a fabricating method of a high aspect ratio structure according to another embodiment of the invention.

It should be noted that FIG. 5A to FIG. 5C are schematic cross-sectional views illustrating the fabricating method of the high aspect ratio structure 200 shown in FIG. 2, for example. Because the high aspect ratio structure 200 and the high aspect ratio structure 100a of FIG. 1A differ in the structures of the substrate 10a, the support structures 21, and the dielectric material layer 12, the following paragraphs only describe the fabricating method of the substrate 10a, the support structures 21, and the dielectric material layer 12a of the high aspect ratio structure 200. The fabricating method of the other elements has been specified as above and thus is not repeated hereinafter.

With reference to FIG. 5A and FIG. 5B, a substrate 10 is provided. Next, the substrate 10 is patterned to form a patterned substrate 10a. The substrate 10a includes a plurality of grooves M2. The groove M2 has a rectangular shape, a triangular shape, a rhombic shape, or a combination of the foregoing. In FIG. 5B, the groove M2 has the rectangular shape, for example. Next, a support material layer 61 is formed conformally on the substrate 10a. The support material layer 61 conformally covers the substrate 10a and the grooves M2 of the substrate 10a, for example.

It should be noted that, in this embodiment, because the support material layer 61 does not fill the grooves M2 of the substrate 10a, the support material layer 61 in the grooves M2 of the substrate 10a substantially forms grooves N2. That is to say, a plurality of grooves N2 are formed simultaneously, as shown in FIG. 5B, when the support material layer 61 is formed. The width of the groove N2 is smaller than the width of the groove M2 of the substrate 10a, for example. A material of the support material layer 61 may be the same as the material of the support material layer 11a as specified above. A method of forming the support material layer 61 includes performing chemical vapor deposition or metal organic chemical vapor deposition (MOCVD).

With reference to FIG. 5C, a dielectric material layer 12a is formed on the support material layer 61. The material and forming method of the dielectric material layer 12a have been specified above. It should be noted that, because the support material layer 61 includes a plurality of grooves N2, the dielectric material layer 12a formed in the subsequent process covers the support material layer 61 and is embedded in the grooves N2 of the support material layer 61 to be properly bonded to the support material layer 61.

Details of the subsequent process may be understood by referring to FIG. 4D to FIG. 4E, and a plurality of composite layers 18a are formed on the dielectric material layer 12a. Thereafter, a support material layer 20a, an advanced patterning film 52, a dielectric anti-reflective coating film 54, a bottom anti-reflective coating film 56, and a patterned photoresist layer 58 are formed in sequence on the top composite layer 18a. Then, the high aspect ratio structure 200 shown in FIG. 2 is formed by performing an etching process on the substrate 10a with the patterned photoresist layer 58 as a mask.

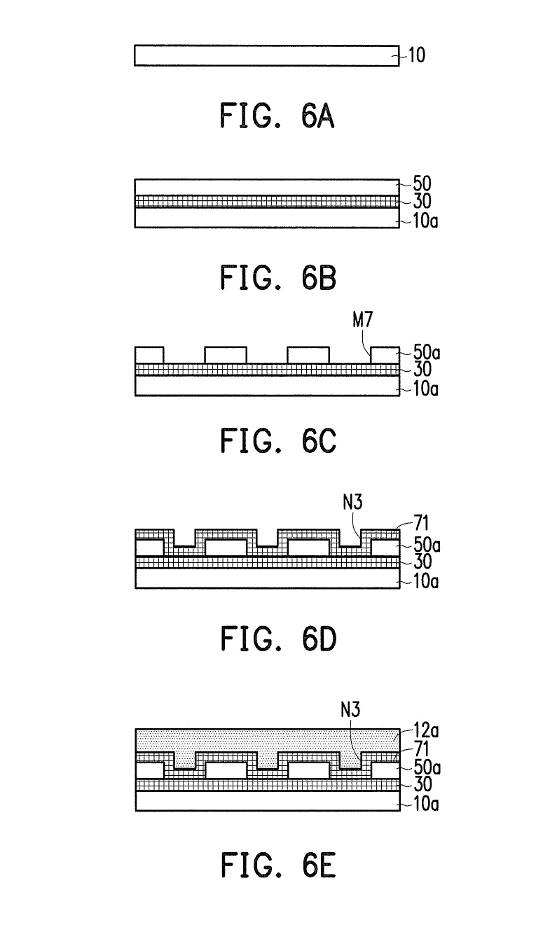

FIG. 6A to FIG. 6E are schematic cross-sectional views illustrating a fabricating method of a high aspect ratio structure according to yet another embodiment of the invention.

FIG. 6A to FIG. 6E are schematic cross-sectional views illustrating a fabricating method of the high aspect ratio structure 300 shown in FIG. 3. Like a part of the fabricating method of the high aspect ratio structure 200, the following paragraphs only describe the fabricating process before the formation of the dielectric material layer 12a, and the fabricating method of the other elements is the same as that described in the embodiment of the high aspect ratio structure 100a and is not repeated hereinafter.

With reference to FIG. 6A and FIG. 6B, a substrate 10 is provided. Next, a support layer 30 is formed on the substrate 10. A method of forming the support layer 30 includes performing chemical vapor deposition or metal organic chemical vapor deposition (MOCVD). A thickness of the support layer 30 is in a range of 10 nm to 300 nm, for example. Next, a dielectric material layer 50 is formed on the support layer 30. A method of forming the dielectric material layer 50 includes performing thermal oxidation or chemical vapor deposition, for example. A thickness of the dielectric material layer 50 is in a range of 10 nm to 300 nm, for example.

With reference to FIG. 6C and FIG. 6D, a lithography and etching process are performed on the dielectric material layer 50 to form a patterned dielectric material layer 50a and a plurality of grooves M7. Then, a support material layer 71 is formed conformally on the substrate 10. The support material layer 71 is formed conformally on the patterned dielectric material layer 50a and the grooves M7, for example.

In this embodiment, because the support material layer 71 does not fill the grooves M7, the support material layer 71 in the grooves M7 substantially forms grooves N3. That is to say, a plurality of grooves N3 are formed simultaneously, as shown in FIG. 7D, when the support material layer 71 is formed. The width of the groove N3 is smaller than the width of the groove M7, for example. A material of the support material layer 71 may be the same as the material of the support material layer 11a as specified above. In an embodiment, the material of the support material layer 71 is the same as the material of the support layer 30 below. However, it should be noted that the invention is not limited thereto. A method of forming the support material layer 71 includes performing chemical vapor deposition or metal organic chemical vapor deposition (MOCVD).

With reference to FIG. 6E, a dielectric material layer 12a is formed on the support material layer 71. In this embodiment, because the support material layer 71 includes a plurality of grooves N3, the dielectric material layer 12a formed in the subsequent process covers the support material layer 71 and is located in the grooves N3 of the support material layer 71 to be properly bonded to the support material layer 71. Details of the subsequent process may be understood by referring to FIG. 4D. Afterwards, similar to the fabricating process of FIG. 4E, the support layer 30 is exposed by performing an etching process to etch and remove the support material layer 71 outside the grooves M7 and the patterned dielectric material layer 50a between adjacent two grooves M7, so as to form the high aspect ratio structure 300 shown in FIG. 3.

In conclusion of the above, in the high aspect ratio structure provided by the invention, the support structure is formed between the substrate and the stack structure to improve the strength at the bottom of the high aspect ratio structure and prevent bending or collapse of the stack structure. In particular, for the structure having the trench of higher aspect ratio between the stack structures, by disposing the support structure having greater Young's modulus than the material layer under the stack structure, the overall Young's modulus of the high aspect ratio structure is improved. Moreover, each support structure has the concave-convex surface, such that the support structure can be fitted to the stack structure thereover or the substrate thereunder, thereby improving the strength and anti-collapse property of the high aspect ratio structure and preventing bending or collapse.

It will be apparent to those skilled in the art that various modifications and variations can be made to the disclosed embodiments without departing from the scope or spirit of the invention. In view of the foregoing, it is intended that the invention covers modifications and variations provided that they fall within the scope of the following claims and their equivalents.

1. A high aspect ratio structure, comprising:
a substrate;
a plurality of stack structures disposed on the substrate, wherein a trench is formed between adjacent two stack structures, and each of the stack structures comprises:
a plurality of first material layers; and
a plurality of second material layers disposed alternately with the first material layers; and
a plurality of support structures respectively disposed between the substrate and the stack structures, wherein each of the support structures comprises a concave-convex surface.

2. The high aspect ratio structure according to claim 1, wherein the concave-convex surface comprises a rectangular shape, a triangular shape, a rhombic shape, or a combination of the foregoing.

3. The high aspect ratio structure according to claim 1, wherein the substrate comprises a plurality of first grooves, and the support structures are respectively embedded in the first grooves of the substrate.

4. The high aspect ratio structure according to claim 3, wherein the support structures fill the first grooves of the substrate and cover a portion of a surface of the substrate.

5. The high aspect ratio structure according to claim 3, wherein the support structures are disposed in the first grooves of the substrate and formed conformally with the first grooves, and each of the support structures comprises a second groove.

6. The high aspect ratio structure according to claim 5, further comprising a plurality of first dielectric layers respectively embedded in the second groove of each of the support structures and covering a surface of the support structure.

7. The high aspect ratio structure according to claim 6, wherein a shape of the first dielectric layer comprises a T shape.

8. The high aspect ratio structure according to claim 3, wherein a shape of the first groove comprises a rectangular shape, a triangular shape, a rhombic shape, or a combination of the foregoing.

9. The high aspect ratio structure according to claim 1, further comprising a first support layer disposed between the substrate and the support structures.

10. The high aspect ratio structure according to claim 9, further comprising a plurality of first dielectric layers respectively embedded in a second groove of each of the support structures and covering a surface of the support structure.

11. The high aspect ratio structure according to claim 10, wherein a shape of the first dielectric layer comprises a T shape.

12. The high aspect ratio structure according to claim 1, wherein a shape of the support structure comprises a T shape, a U shape, a nail shape, or a combination of the foregoing.

13. The high aspect ratio structure according to claim 1, wherein a Young's modulus of the support structure is greater than a Young's modulus of the first material layers or a Young's modulus of the second material layers.

14. The high aspect ratio structure according to claim 1, wherein a material of the support structures comprises silicon nitride, silicon carbide, metalloid, or a combination of the foregoing.

15. The high aspect ratio structure according to claim 1, further comprising a plurality of second support layers respectively disposed on the stack structures.

16. The high aspect ratio structure according to claim 1, wherein an aspect ratio of the trench is in a range of 10-180.

17. The high aspect ratio structure according to claim 1, further comprising:
a plurality of conductive pillars disposed in the trenches; and
a charge storage layer disposed between the stack structures and the conductive pillars.

18. The high aspect ratio structure according to claim 1, wherein at least a portion of each of the support structures is embedded in the substrate.

19. The high aspect ratio structure according to claim 18, wherein at least a portion of the support structures protrudes on a surface of the substrate.

20. The high aspect ratio structure according to claim 1, wherein the first material layers and the second material layers comprise conductive material, dielectric material or the combination thereof.
